(19) United States
(12) Patent Application Publication
(10) Pub. No.: US 2019/0214271 A1
(43) Pub. Date: Jul. 11, 2019

(54) SEMICONDUCTOR DEVICE

(71) Applicant: Mitsubishi Electric Corporation, Chiyoda-ku (JP)

(72) Inventors: Hiroyoshi SUZUKI, Tokyo (JP); Hiroaki OKABE, Tokyo (JP)

(73) Assignee: Mitsubishi Electric Corporation, Chiyoda-ku (JP)

(21) Appl. No.: 16/316,150

(22) PCT Filed: Jul. 7, 2017
(86) PCT No.: PCT/JP2017/024954

§ 371 Date: Jan. 8, 2019

(30) Foreign Application Priority Data
Aug. 22, 2016 (JP) 2016-161751

(51) Int. Cl. H01L 21/3205; H01L 21/768; H01L 23/532

(52) U.S. Cl. CPC H01L 21/32051; H01L 21/768; H01L 2224/05147; H01L 2224/4847; H01L 2224/4911; H01L 23/5329

(57) ABSTRACT

The object of the present invention is to suppress cracks in the interlayer insulating film attributed to growth of Cu crystal grains. The semiconductor device (101) includes a source region (5), an interlayer insulating film (7) made of silicon oxide, having an opening portion, and formed on the source region (5), a Cu electrode (1) electrically connected to the source region (5) through the opening portion of the interlayer insulating film (7) and an end portion thereof is located on the interlayer insulating film (7) inside an end portion of the interlayer insulating film (7), and a stress relieving layer (13) formed between the Cu electrode (1) and the interlayer insulating film (7), made of a material having a higher fracture toughness value than the interlayer insulating film (7), and extending from the inside to the outside of the end portion of the Cu electrode (1).

### TECHNICAL FIELD

The present invention relates to a structure for relieving an impact during wire bonding of a semiconductor device.

### BACKGROUND ART

Silicon carbide (SiC) has a larger band gap than silicon (Si). Therefore, a semiconductor element using SiC can operate at a higher temperature than a semiconductor element using Si which operates at less than 200° C.

A surface electrode mainly composed of aluminum (Al) is used for a semiconductor element operating at less than 200° C., an Al wire is bonded to the surface electrode, and when such semiconductor elements are operated at a temperature exceeding 200° C., there is a problem that the shape of the surface electrode and the wire are changed and reliability thereof is lowered. Therefore, copper (Cu) with high reliability at high temperature has been studied as a material of the surface electrode and the wire in place of Al.

However, as compared with an Al wire, a Cu wire has a large impact on an element when bonding to the surface electrode, therefore, there is a problem of element defect. Accordingly, when a Cu wire is used, it is necessary to devise the structure of the surface electrode to which the Cu wire is bonded.

In this respect, in Patent Document 1, it has been proposed that an impact absorbing beam is formed by opening an interlayer insulating film formed on a pad of an integrated circuit or the collector electrode of the semiconductor element, and a Cu thick film electrode, that is connected to the collector electrode through the opening portion of the interlayer insulating film is formed on the collector electrode of the element, thereby the impact occurring at the time of bonding the wire to the thick film electrode is relieved or absorbed with the Cu thick film electrode and the impact absorbing beam.

### PRIOR ART DOCUMENTS

### Patent Documents

[Patent Document 1] Japanese Patent Application Laid-Open No. 2006-165515

### SUMMARY

### Problem to be Solved by the Invention

However, in the structure of Patent Document 1, the Cu electrode is bonded to the interlayer insulating film through only a barrier metal layer, therefore, when the Cu electrode becomes high in temperature during manufacture of the product or during operation of the element, the Cu electrode contracts due to the growth of the crystal grains in the Cu electrode, and stress is applied to the interlayer insulating film, as a result, the interlayer insulating film might crack.

In view of the above problem, the object of the present invention is to suppress cracks in the interlayer insulating film due to the growth of Cu crystal grains.

### Means to Solve the Problem

The semiconductor device according to the present invention includes a semiconductor layer, an interlayer insulating film made of silicon oxide, having an opening portion, and formed on the semiconductor layer, a Cu electrode electrically connected to the semiconductor layer through the opening portion of the interlayer insulating film and an end portion thereof is located on the interlayer insulating film inside an end portion of the interlayer insulating film, and a stress relieving layer formed between the Cu electrode and the interlayer insulating film, made of a material having a higher fracture toughness value than the interlayer insulating film, and extending from the inside to the outside of the end portion of the Cu electrode.

### Effects of the Invention

The semiconductor device according to the present invention includes a semiconductor layer, an interlayer insulating film made of silicon oxide, having an opening portion, and formed on the semiconductor layer, a Cu electrode electrically connected to the semiconductor layer through the opening portion of the interlayer insulating film and an end portion thereof is located on the interlayer insulating film inside an end portion of the interlayer insulating film, and a stress relieving layer formed between the Cu electrode and the interlayer insulating film, made of a material having a higher fracture toughness value than the interlayer insulating film, and extending from the inside to the outside of the end portion of the Cu electrode. Therefore, the interlayer insulating film and the Cu electrode absorb impacts during Cu wire bonding, and element defect of the semiconductor element can be suppressed. In addition, the stress generated from the Cu electrode attributed to the growth of Cu crystal grains at high temperature can be relieved by the stress relieving layer, therefore, occurrence of cracks in the interlayer insulating film can be suppressed.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view illustrating a configuration of a power semiconductor element according to Embodiment 1.

FIG. 2 is a cross-sectional view illustrating a configuration of a semiconductor device according to Embodiment 1.

FIG. 3 is a cross-sectional view illustrating a configuration of a semiconductor device according to Modification of Embodiment 1.

FIG. 4 is a cross-sectional view illustrating a configuration of a semiconductor device according to Embodiment 2.

FIG. 5 is a cross-sectional view illustrating a configuration of a semiconductor device according to Embodiment 3.

FIG. 6 is a cross-sectional view illustrating a configuration of a semiconductor device according to Modification of Embodiment 3.

FIG. 7 is a cross-sectional view illustrating a configuration of a semiconductor device according to Embodiment 4.

### DESCRIPTION OF EMBODIMENTS

### A. Embodiment 1

<A-1. Configuration>

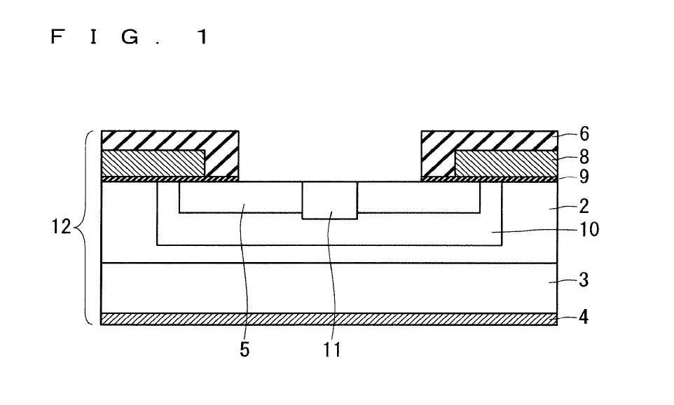

FIG. 1 is a cross-sectional view illustrating a configuration of a power semiconductor element according to Embodiment 1. Hereinafter, the configuration of the power semiconductor element 12 will be described. For a substrate of the power semiconductor element 12, a SiC substrate 3 is used, and an element structure is formed thereon. If the SiC substrate is used, a low-loss semiconductor element capable of a high speed operation and a high-temperature operation as compared with the conventionally used Si substrate can be fabricated. In FIG. 1, the power semiconductor element 12 is shown as a Metal-Oxide-Semiconductor Field-Effect-Transistor (MOSFET).

On the surface side of the SiC substrate 3, a drift layer 2 is formed by epitaxial growth, and a rear surface electrode 4 electrically connected to the SiC substrate 3 is formed on the rear surface side thereof. On the surface layer of the drift layer 2, a base region 10 is partially formed, and a source region 5 is partially formed on the surface layer of the base region 10. A surface of the base region 10 between the source region 5 and the drift layer 2 is a channel region of the power semiconductor element 12. The base contact region 11 is formed so as to penetrate through the source region 5 from the surface of the source region 5 and reach the base region 10. The base region 10, the source region 5, and the base contact region 11 are formed by ion implantation and activation annealing.

On the channel region of the power semiconductor element 12, a gate electrode 8 is formed through a gate oxide film 9. That is, the channel region is opposite to the gate electrode 8 through the gate oxide film 9, and an inversion layer is formed during the on-operation. Silicon oxide (SiO₂) can be used for the gate oxide film 9 and polysilicon can be used for the gate electrode 8. The gate electrode 8 is covered with an interlayer insulating film 6 having a contact hole. SiO₂ can be used for the interlayer insulating film 6. The above is the configuration of the power semiconductor element 12.

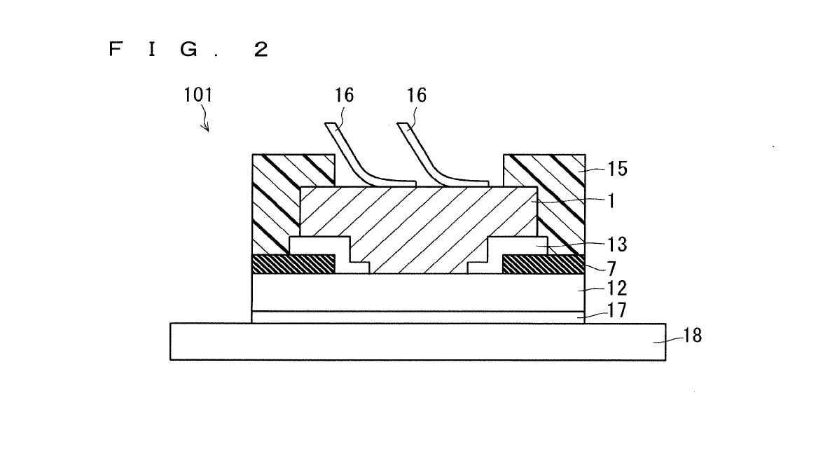

FIG. 2 is a cross-sectional view illustrating a configuration of a semiconductor device 101 including the power semiconductor element 12. Hereinafter, the configuration of the semiconductor device 101 will be described. On the surface of the power semiconductor element 12, an interlayer insulating film 7 made of SiO₂ is partially formed. The interlayer insulating film 7 is formed in a region where a Cu electrode 1 is formed in plan view so as to surround the center of the Cu electrode 1 with an opening portion with respect to the center of the Cu electrode 1. Therefore, a part of the interlayer insulating film 7 is also formed under the Cu electrode 1. Also, the end portion of the interlayer insulating film 7 is located outside the end portion of the Cu electrode 1.

A stress relieving layer 13 is formed on the interlayer insulating film 7. As with the interlayer insulating film 7, the stress relieving layer 13 has an opening portion with respect to the center of the Cu electrode 1, and the opening width thereof is smaller than the opening width of the interlayer insulating film 7. Therefore, at the opening portion of the interlayer insulating film 7, the end portion of the interlayer insulating film 7 is covered with the stress relieving layer 13. The stress relieving layer 13 is made of a material having a fracture toughness value higher than that of the interlayer insulating film 7 made of SiO₂. As a material of the stress relieving layer 13, Al, polyimide, silicon nitride and so forth can be listed, for example. The thickness of the stress relieving layer 13 is desirably 100 nm or more, and if it is 200 nm or more, the occurrence of cracks in the interlayer insulating film 7 can be more reliably suppressed. When silicon nitride is used as the material of the stress relieving layer 13, it has been experimentally confirmed that, by setting the thickness to 200 nm, the occurrence of cracks in the interlayer insulating film 7 can be suppressed even when a relatively thick Cu electrode having a thickness exceeding 30 μm is formed.

The Cu electrode 1 is formed on the stress relieving layer 13. More specifically, the Cu electrode 1 is electrically connected to the source region 5 of the power semiconductor element 12 through the stress relieving layer 13 at the opening portion of the stress relieving layer 13, and the Cu electrode 1 operates as a surface electrode of the power semiconductor element 12. The thickness of the Cu electrode 1 is, for example, 15 μm or more. This is thus configured for relieving the impact applied to the power semiconductor element 12 at the time of bonding the Cu wires 16 to the Cu electrode 1 to prevent element destruction of the power semiconductor element 12.

As illustrated in FIG. 2, the end portion of the Cu electrode 1 is located inside the end portion of the stress relieving layer 13. That is, in FIG. 2, the left end of the Cu electrode 1 is located on the right side of the left end of the stress relieving layer 13, and the right end of the Cu electrode 1 is located on the left side of the right end of the stress relieving layer 13.

The interlayer insulating film 7, the stress relieving layer 13, and the Cu electrode 1 are covered with a polyimide 15. The polyimide 15 is formed from the tip end of the power semiconductor element 12 over the Cu electrode 1 and functions as a protective layer.

The polyimide 15 has an opening portion on the Cu electrode 1, and the Cu wires 16 are bonded to the Cu electrode 1 at the opening portion thereof. In the power semiconductor, the amount of current to be handled is large, therefore, a thick wire having a diameter of 100 μmφ or more is used for the Cu wire 16 so that a large current can flow. The number of Cu wires 16 may be one, or may be plural depending on the amount of current extracted from the power semiconductor element 12. Although pure Cu can be used as the material of the Cu wire 16, however, it is not limited thereto, and a material having Cu as a main component and having a Cu content of 50% or more in a weight ratio can be used. Also, the Cu wire 16 in which Cu is coated with Al or other metal or an organic film may be used.

The rear surface of the power semiconductor element 12 is electrically and mechanically bonded to a base plate 18 by a bonding material 17 such as solder.

In the related art, there has been a problem that, when the Cu electrode 1 becomes high in temperature during product manufacturing or device operation, Cu crystal grains of Cu electrode 1 grow, then stress is applied to the interlayer insulating film 7 under the Cu electrode 1, and this attributes to cracks generated in the interlayer insulating film 7. However, according to the configuration of the semiconductor device 101 of Embodiment 1, the stress relieving layer 13 is present between the Cu electrode 1 and the interlayer insulating film 7, therefore, the stress attributed to the growth of the Cu crystal grains is absorbed by the stress relieving layer 13, and the cracking in the interlayer insulating film 7 can be suppressed.

<A-2. Modification>

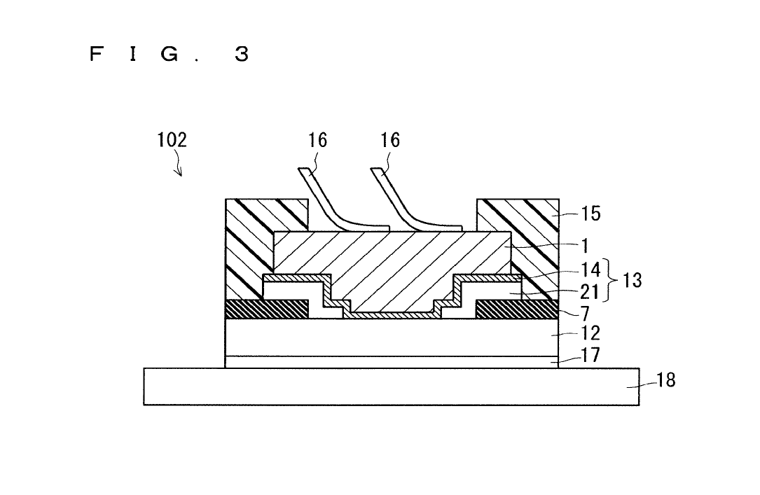

A part or the whole of the stress relieving layer 13 may be constituted by a barrier metal layer 14 having a higher fracture toughness value than the interlayer insulating film 7 made of SiO₂. FIG. 3 is a cross-sectional view illustrating a structure of a semiconductor device 102 in which a part of the stress relieving layer 13 is constituted by the barrier metal layer 14. Apart from the stress relieving layer 13, the configuration of the semiconductor device 102 is similar to that of the semiconductor device 101.

The stress reliving layer 13 other than the barrier metal layer 14 is referred to as a non-barrier metal stress reliving layer 21. That is, in the semiconductor device 102, the stress reliving layer 13 includes the non-barrier metal stress reliving layer 21 and the barrier metal layer 14. The non-barrier metal stress relieving layer 21 has an opening portion at a position overlapping the center of the Cu electrode 1 in plan view. The barrier metal layer 14 is formed to cover the non-barrier metal stress relieving layer 21 and the opening portion thereof. By the barrier metal layer 14, diffusion of Cu into the source region 5 and the non-barrier metal stress relieving layer 21 can be prevented. For the barrier metal layer 14, metal such as tungsten (W), tantalum (Ta), molybdenum (Mo), and titanium (Ti), nitride such as titanium nitride (TiN), titanium silicon nitride (TiSiN), tungsten nitride (WN), and tantalum nitride (TaN), metal carbide such as tantalum carbide (TaC), and titanium carbide (TiC), is used.

In the above description, the SiC substrate is used as the semiconductor substrate of the power semiconductor element 12, however, another semiconductor substrate such as a Si substrate may be used. In addition to the MOSFET, the power semiconductor element 12 may be another power semiconductor element such as an Insulated Gate Bipolar Transistor (IGBT) or the like, a power semiconductor element having an insulated gate electrode, a Schottky barrier diode, a PN diode, or the like.

<A-3. Effect>

The semiconductor device 101 according to Embodiment 1 includes the source region 5 being a semiconductor layer, the interlayer insulating film 7 made of silicon oxide, having an opening portion, and formed on the source region 5, the Cu electrode 1 electrically connected to the source region 5 through the opening portion of the interlayer insulating film 7 and the end portion thereof is located on the interlayer insulating film 7 inside the end portion of the interlayer insulating film 7, and the stress relieving layer 13 formed between the Cu electrode 1 and the interlayer insulating film 7, made of a material having a higher fracture toughness value than the interlayer insulating film 7, and extending over from the inside to the outside of the end portion of the Cu electrode 1. Therefore, the interlayer insulating film 7 and the Cu electrode 1 absorb impact during Cu wire bonding, and element defect of the semiconductor element can be suppressed. In addition, the stress generated from the Cu electrode 1 attributed to the growth of Cu crystal grains at high temperature can be relieved by the stress relieving layer 13, therefore, the occurrence of cracks in the interlayer insulating film 7 can be suppressed.

In the semiconductor device 101, the stress relieving layer 13 having an opening portion is formed on the opening portion of the interlayer insulating film 7, and the end of the opening portion of the stress relieving layer 13 is located inside of the end of the opening portion of the interlayer insulating film 7. Therefore, the Cu electrode 1 is electrically connected to the source region 5 through the opening portion of the stress relieving layer 13 and the opening portion of the interlayer insulating film 7.

In addition, in the semiconductor device 102, part or whole of the stress relieving layer 13 is the barrier metal layer 14, therefore, diffusion of Cu into the source region 5 can be prevented by the barrier metal layer 14.

Also, in the semiconductor device 102, the stress relieving layer 13 includes the barrier metal layer 14 and the non-barrier metal stress relieving layer 21, and the non-barrier metal stress relieving layer 21 having an opening portion is formed on the opening portion of the interlayer insulating film 7, the barrier metal layer 14 is formed over from above the source region 5 in the opening portion of the non-barrier metal stress relieving layer 21 over the non-barrier metal stress relieving layer 21, and the end portion thereof is located outside the end portion of the Cu electrode. Therefore, diffusion of Cu into the stress relieving layer 13 can be prevented by the barrier metal layer 14.

In addition, in the semiconductor devices 101 and 102, by setting the thickness of the Cu electrode 1 to 15 μm or more, the impact of Cu wire bonding can be relieved by the Cu electrode 1, and element defect of the power semiconductor element 12 can be suppressed.

Further, in the semiconductor devices 101 and 102, by setting the thickness of the stress relieving layer 13 to 100 nm or more, the stress on the interlayer insulating film 7 attributed to Cu crystal growth can be relieved. Furthermore, if the thickness of the stress relieving layer 13 is set to 200 nm or more, the stress on the interlayer insulating film 7 attributed to the Cu crystal growth can be relieved more reliably, and the occurrence of cracks in the interlayer insulating film 7 can be suppressed.

Further, the Cu wires 16 are bonded onto the Cu electrodes 1 of the semiconductor devices 101 and 102. According to the configuration of the semiconductor devices 101 and 102, while relieving the impact on the power semiconductor element 12 by Cu wire bonding to the Cu electrode 1, the occurrence of cracks in the interlayer insulating film 7 attributed to the growth of the Cu crystal grains can be suppressed.

Further, by using the SiC substrate for the substrate of the power semiconductor element 12 and the SiC layer for the source region 5, a low-loss semiconductor device capable of the high speed operation and the high-temperature operation can be obtained.

### B. Embodiment 2

<B-1. Configuration>

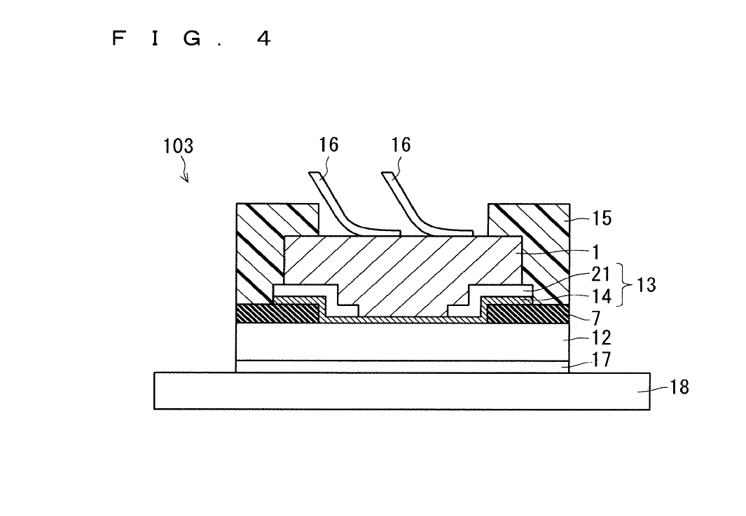

FIG. 4 is a cross-sectional view illustrating a configuration of a semiconductor device 103 according to Embodiment 2. The semiconductor device 103 is similar to the semiconductor device 102 in that a part of the stress relieving layer 13 is formed of the barrier metal layer 14 having a higher fracture toughness value than the interlayer insulating film 7 made of SiO₂, however, the semiconductor device 103 differs from the semiconductor device 102 in that the barrier metal layer 14 is provided between the interlayer insulating film 7 and the non-barrier metal stress relieving layer 21. Apart from the above, the configuration of the semiconductor device 103 is similar to that of the semiconductor device 102.

In the semiconductor device 102, the barrier metal layer 14 is provided between the Cu electrode 1 and the non-barrier metal stress relieving layer 21 so that Cu of the Cu electrode does not diffuse in the stress relieving layer 13. However, when the non-barrier metal stress relieving layer 21 is made of a material which does not diffuse Cu to the inside even when coming into contact with Cu, the barrier metal layer 14 may be provided over from above the opening portion of the interlayer insulating film 7 to above the interlayer insulating film 7, that is, between the non-barrier metal stress relieving layer 21 and the interlayer insulating film 7. Even with such a configuration, the barrier metal layer 14 is present between the source region 5 and the Cu electrode 1, therefore, diffusion of Cu into the source region 5 can be prevented.

According to the semiconductor device 103 of Embodiment 2, in addition to the effects of Embodiment 1, the following effects are obtained. That is, the end portion of the Cu electrode 1 does not contact the barrier metal layer 14, therefore, damage to the barrier metal layer 14 attributed to stress generated due to the growth of Cu crystal grains at high temperature can be suppressed. Therefore, reliability of the high-temperature operation can be enhanced.

<B-2. Effect>

According to the semiconductor device 103 of Embodiment 2, the stress relieving layer 13 includes the barrier metal layer 14 and the non-barrier metal stress relieving layer 21, and the barrier metal layer 14 is formed over from the semiconductor layer 5 in the opening portion of the interlayer insulating film 7 to above the interlayer insulating film 7. That is, the barrier metal layer 14 is formed between the non-barrier metal stress relieving layer 21 and the interlayer insulating film 7. Accordingly, the end portion of the Cu electrode 1 does not contact the barrier metal layer 14, therefore, damage to the barrier metal layer 14 attributed to stress generated due to the growth of Cu crystal grains at high temperature can be suppressed, and thus reliability of the high-temperature operation can be enhanced.

Further, in the semiconductor device 103, by setting the thickness of the stress relieving layer 13, that is, the total thickness of the barrier metal layer 14 and the non-barrier metal stress relieving layer 21 to 100 nm or more, the stress on the interlayer insulating film 7 by Cu crystal growth can be relieved. Furthermore, if the thickness of the stress relieving layer 13, that is, the total thickness of the barrier metal layer 14 and the non-barrier metal stress relieving layer 21 is set to 200 nm or more, the stress on the interlayer insulating film 7 attributed to the Cu crystal growth can be relived more reliably, and the occurrence of cracks in the interlayer insulating film 7 can be suppressed.

### C. Embodiment 3

<C-1. Configuration>

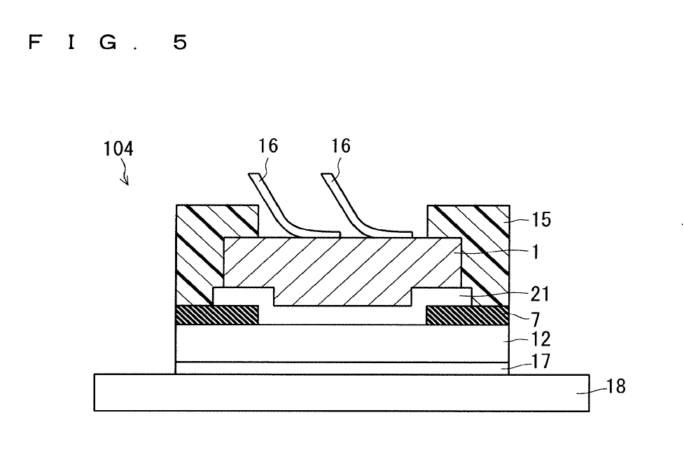

FIG. 5 is a cross-sectional view illustrating a configuration of a semiconductor device 104 according to Embodiment 3. In Embodiment 1 and Embodiment 2, the stress relieving layer 13 has an opening portion on the opening portion of the interlayer insulating film 7, and the Cu electrode 1 and the source region 5 of the power semiconductor element 12 are electrically connected through the opening portion of the stress relieving layer 13. Meanwhile, in Embodiment 3, the configuration is that the stress relieving layer 13 is formed all over the lower side of Cu electrode 1, over from the opening portion of the interlayer insulating film 7 to above the interlayer insulating film 7. Even with such a structure, by forming the stress relieving layer 13 with an electric conductor, the Cu electrode 1 electrically connected to the source region 5 of the power semiconductor element 12 at the opening portion of the interlayer insulating film 7, through the stress relieving layer 13. As a material of the stress relieving layer 13, Al and so forth can be listed. The thickness of the stress relieving layer 13 is desirably 100 nm or more, and when it is 200 nm or more, the occurrence of cracks in the interlayer insulating film 7 can be more reliably suppressed.

According to the semiconductor device 103 of Embodiment 2, in addition to the effects of Embodiment 1, the following effects are obtained. That is, the Cu electrode 1 is electrically connected to the semiconductor layer of the power semiconductor element 12 through the opening portion of the interlayer insulating film 7, therefore, the electric resistance of the Cu electrode 1 can be lowered compared to that in Embodiment 1. In addition, by covering the entire lower part of the Cu electrode 1 with the stress relieving layer 13, the stress due to the growth of the Cu crystal grains at high temperature is efficiently absorbed into the stress relieving layer 13. Therefore, compare to Embodiment 1, the occurrence of cracks in the interlayer insulating film 7 can be suppressed more reliably, and thus reliability of the high-temperature operation can be enhanced.

<C-2. Modification>

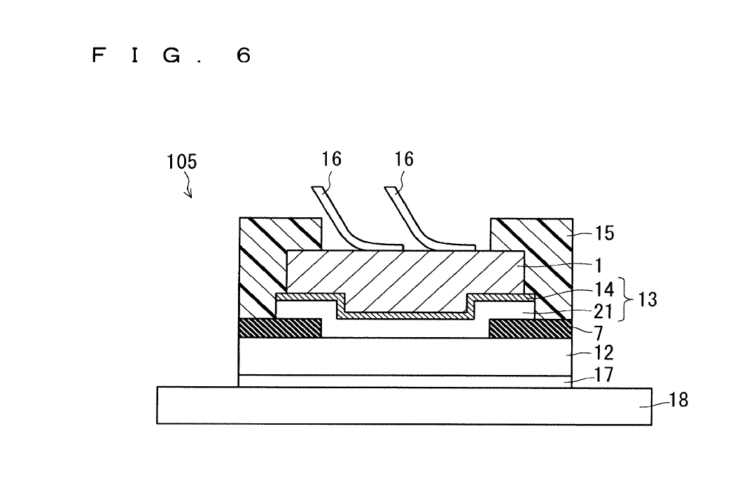

A part or the whole of the stress relieving layer 13 may be constituted by a barrier metal layer 14 having a higher fracture toughness value than the interlayer insulating film 7 made of SiO₂. FIG. 6 is a cross-sectional view illustrating a structure of a semiconductor device 105 in which a part of the stress relieving layer 13 is constituted by the barrier metal layer 14. Apart from the stress relieving layer 13, the configuration of the semiconductor device 105 is similar to that of the semiconductor device 104.

That is, in the semiconductor device 102, the stress reliving layer 13 includes the non-barrier metal stress reliving layer 21 and the barrier metal layer 14. The non-barrier metal stress reliving layer 21 is formed of an electric conductor. As illustrated in FIG. 6, the barrier metal layer 14 is provided, on an upper surface of the non-barrier metal stress relieving layer 21, that is, between the non-barrier metal stress relieving layer 21 and the Cu electrode 1.

<C-3. Effect>

According to the semiconductor device 104 of Embodiment 3, the stress relieving layer 13 is formed of the electric conductor and formed over from the opening portion of the interlayer insulating film 7 to above the interlayer insulating film 7. Accordingly, the Cu electrode 1 is electrically connected to the semiconductor layer of the power semiconductor element 12 through the opening portion of the interlayer insulating film 7, therefore, the electric resistance of the Cu electrode 1 can be lowered. In addition, by covering the entire lower part of the Cu electrode 1 with the stress relieving layer 13, the stress due to the growth of the Cu crystal grains at high temperature is efficiently absorbed into the stress relieving layer 13. Therefore, the occurrence of cracks in the interlayer insulating film 7 can be suppressed, and thus reliability of the high-temperature operation can be enhanced.

Also, in the semiconductor device 105 according to Modification of Embodiment 3, the stress relieving layer 13 includes the barrier metal layer 14 and the non-barrier metal stress relieving layer 21, and the barrier metal layer 14 is provided between the non-barrier metal stress relieving layer 21 and the Cu electrode 1, therefore, diffusion of Cu into the non-barrier metal stress relieving layer 21 can be suppressed.

### D. Embodiment 4

<D-1. Configuration>

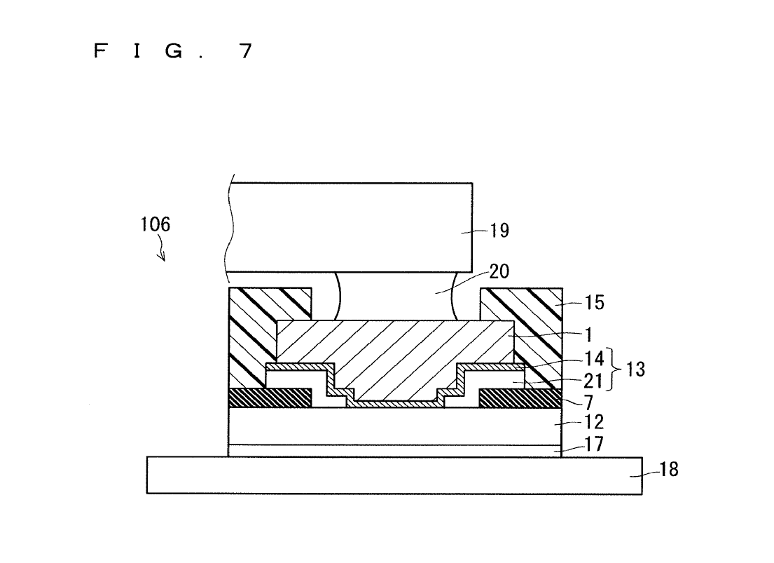

FIG. 7 is a cross-sectional view illustrating a configuration of a semiconductor device 106 according to Embodiment 4. In Embodiment 1, Embodiment 2, and Embodiment 3, the Cu wires 16 are bonded to the Cu electrode 1. Whereas in Embodiment 4, a main electrode wiring 19 of the power module is directly bonded to the Cu electrode 1. The main electrode wiring 19 and the Cu electrode 1 may be bonded using a bonding material 20 such as solder shown in FIG. 7, or may be bonded by employing ultrasonic bonding without using a bonding material.

In FIG. 7, the structure between the Cu electrode 1 and the power semiconductor element 12 of the semiconductor device 106 has the same structure as the semiconductor device 102 according to Modification of Embodiment 1. However, the structures may be the same as that of any of the semiconductor devices 101, 103, 104, and 105.

According to the semiconductor device 106 of Embodiment 4, in addition to the effects of Embodiment 1, Embodiment 2, and Embodiment 3, the following effects are obtained. That is, the main electrode wiring 19 is directly bonded to the Cu electrode 1, therefore, the fatigue life of the upper part of the Cu electrode 1 attributed to thermal stress caused by repetition of the switching operation of the power semiconductor element 12 is improved as compared with the case where the Cu wire is used, moreover, the impedance of the power module can be reduced. The thermal stress to the power semiconductor element 12 is increased by directly bonding the main electrode wiring 19 to the Cu electrode 1, however, by providing the stress relieving layer 13, the occurrence of cracks in the interlayer insulating film 7 can be suppressed and thus reliability of the high temperature operation can be enhanced.

<D-2. Effect>

According to the semiconductor device 106 of Embodiment 4, the main electrode wiring 19 is directly bonded to the Cu electrode 1. Accordingly, the fatigue life of the upper part of the Cu electrode 1 attributed to thermal stress caused by repetition of the switching operation of the power device is improved as compared with Embodiment 1, Embodiment 2, and Embodiment 3, moreover, the impedance of the power module can be reduced. In addition, the stress generated from the Cu electrode 1 attributed to the growth of Cu crystal grains at high temperature can be relieved by the stress relieving layer 13, the occurrence of cracks in a field insulating film 7 can be suppressed, and thus the reliability of the high-temperature operation can be enhanced.

It should be noted that Embodiments of the present invention can be arbitrarily combined and can be appropriately modified or omitted without departing from the scope of the invention.

While the invention has been described in detail, the forgoing description is in all aspects illustrative and not restrictive. It is understood that numerous other modifications and variations can be devised without departing from the scope of the invention.

### EXPLANATION OF REFERENCE SIGNS

1 Cu electrode, 2 drift layer, 3 SiC substrate, 4 rear surface electrode, 5 source region, 6, 7 interlayer insulating film, 8 gate electrode, 9 gate oxide film, 10 base region, 11 base contact region, 12 power semiconductor element, 13 stress relieving layer, 14 barrier metal layer, 15 polyimide, 16 Cu wire, 17 bonding material, 18 base plate, 19 main electrode wiring, 20 bonding material, 21 non-barrier metal stress relieving layer, 101, 102, 103, 104, 105, 106, semiconductor device

1: A semiconductor device, comprising:
a semiconductor layer;
an interlayer insulating film made of silicon oxide, having an opening portion, and formed on the semiconductor layer;
a Cu electrode electrically connected to the semiconductor layer through the opening portion of the interlayer insulating film and an end portion thereof is located on the interlayer insulating film inside the end portion of the interlayer insulating film; and
a stress relieving layer formed between the Cu electrode and the interlayer insulating film, made of a material having a higher fracture toughness value than the interlayer insulating film, including an opening portion formed on the opening portion of the interlayer insulating film, and an end of the opening portion of the stress relieving layer being located inside of an end of the opening portion of the interlayer insulating film, and extending over from inside to outside of the end portion of the Cu electrode.

2: The semiconductor device according to claim wherein
a thickness of the stress relieving layer is 100 nm or more.

3: The semiconductor device according to claim 2, wherein
a thickness of the stress relieving layer is 200 nm or more.

4. (canceled)

5: The semiconductor device according to claim 1, wherein
part or whole of the stress relieving layer is the barrier metal layer.

6. (canceled)

7: A semiconductor device, comprising:
a semiconductor layer;
an interlayer insulating film made of silicon oxide, including an opening portion, and formed on the semiconductor layer;
a Cu electrode electrically connected to the semiconductor layer through the opening portion of the interlayer insulating film and an end portion thereof is located on the interlayer insulating film inside the end portion of the interlayer insulating film; and
a stress relieving layer formed between the Cu electrode and the interlayer insulating film, made of a material having a higher fracture toughness value than the interlayer insulating film, and extending over from inside to outside of the end portion of the Cu electrode,
the stress reliving layer including a barrier metal layer and a non-barrier metal stress reliving layer,
the barrier metal layer being formed over from the semiconductor layer in the opening portion of the interlayer insulating film to above the interlayer insulating film.

8: A semiconductor device, comprising:
a semiconductor layer;
an interlayer insulating film made of silicon oxide, including an opening portion, and formed on the semiconductor layer;
a Cu electrode electrically connected to the semiconductor layer through the opening portion of the interlayer insulating film and an end portion thereof is located on the interlayer insulating film inside the end portion of the interlayer insulating film; and
a stress relieving layer formed between the Cu electrode and the interlayer insulating film, made of an electric conductor having a higher fracture toughness value than the interlayer insulating film, and provided over from above the opening portion of the interlayer insulating film to above the interlayer insulating film.

9: The semiconductor device according to claim 8,
wherein the stress reliving layer includes a barrier metal layer and a non-barrier metal stress reliving layer, and
wherein the barrier metal layer is provided between the non-barrier metal stress reliving layer and the Cu electrode.

10: The semiconductor device according to claim 1, wherein
a thickness of the Cu electrode is 15 μm or more.

11: The semiconductor device according to claim 1, wherein
the Cu wire is bonded onto the Cu electrodes.

12-13. (canceled)

14: The semiconductor device according to claim 7, wherein
a thickness of the Cu electrode is 15 μm or more.

15: The semiconductor device according to claim 8, wherein
a thickness of the Cu electrode is 15 μm or more.

16: The semiconductor device according to claim 7, wherein
the Cu wire is bonded onto the Cu electrodes.

17: The semiconductor device according to claim 8, wherein
the Cu wire is bonded onto the Cu electrodes.
